(19) United States
(12) Patent Application Publication
(10) Pub. No.: US 2020/0094647 A1
(43) Pub. Date: Mar. 26, 2020

(54) COOLING STRUCTURE OF ON-VEHICLE PROJECTOR

(71) Applicant: TOYODA GOSEI CO., LTD., Kiyosu-shi (JP)

(72) Inventors: Minoru SHIBATA, Kiyosu-shi (JP); Hirotaka OKADA, Kiyosu-shi (JP); Renge ASAKAWA, Kiyosu-shi (JP); Yuhki ICHIKAWA, Kiyosu-shi (JP)

(21) Appl. No.: 16/550,623

(22) Filed: Aug. 26, 2019

(30) Foreign Application Priority Data
Sep. 24, 2018 (JP) 2018-178198

(51) Int. Cl. B60H 1/00; G03B 21/16; H05K 7/20

(52) U.S. Cl. CPC B60H 1/00264; H05K 7/20145; H05K 7/2039; G03B 21/16

(57) ABSTRACT

A cooling structure of an on-vehicle projector, includes: a projector including: a light source; an image projection part configured to project an image based on the light emitted from the light source and an image signal; and first and second vent holes configured to ventilate the internal space, in which the light source is arranged, with the outside; and an air introduction part configured to introduce conditioned air, sent from an air conditioner mounted in a vehicle, to the internal space through the first vent hole.

### CROSS-REFERENCE TO RELATED APPLICATION(S)

This application is based upon and claims the benefit of priority from prior Japanese patent application No. 2018-178198 filed on Sep. 24, 2018, the entire contents of which are incorporated herein by reference.

### BACKGROUND

### 1. Field of the Invention

The invention relates to a cooling structure for cooling a light source of a projector mounted in a vehicle.

### 2. Description of the Related Art

In the related art, a projector such as a tablet terminal is proposed which enables a pointing operation on a projected image for a person to operate a touch panel with a hand according to an intuition (for example, see JP-A-2007-207056).

In such a projector, a large current is applied to secure a luminance of a light source and, thus, the temperature of the light source is increased. Thus, air is sent by an air blowing fan to cool the light source.

However, when the above-described projector is mounted in the vehicle and a vehicle body receives direct sunlight, thereby increasing the inner temperature of the vehicle cabin, the light source cannot be cooled effectively even though the high-temperature air in the vehicle cabin is blown by the air blowing fan. There is a concern that the operation of the projector may interfere.

### SUMMARY

The invention has been made in consideration of the above circumstances, and an object thereof is to provide a cooling structure of an on-vehicle projector capable of cooling a light source effectively.

According to an aspect of the invention, there is provided a cooling structure of an on-vehicle projector, including: a projector including: a light source; an image projection part configured to project an image based on the light emitted from the light source and an image signal; and first and second vent holes configured to ventilate the internal space, in which the light source is arranged, with the outside; and an air introduction part configured to introduce conditioned air, sent from an air conditioner mounted in a vehicle, to the internal space through the first vent hole.

With the cooling structure of the on-vehicle projector of the invention, the conditioned air sent from the air conditioner mounted in the vehicle is introduced from the air introduction part to the internal space through the first vent hole. Therefore, the heating light source can be cooled effectively and the conditioned air can be exhausted from the second vent hole. Thus, the effect of eliminating the thermal effect such as the decrease of life is obtained while the luminance of the light source in the on-vehicle projector is secured.

### BRIEF DESCRIPTION OF THE DRAWINGS

The present invention will become more fully understood from the detailed description given hereinbelow and the accompanying drawing which is given by way of illustration only, and thus is not limitative of the present invention and wherein:

FIG. 1 is a side cross-sectional view schematically illustrating a cooling structure of an on-vehicle projector according to a first embodiment;

FIG. 2 is a block configuration diagram schematically illustrating a configuration of the projector;

FIG. 3 is a side cross-sectional view schematically illustrating a cooling structure of an on-vehicle projector according to a second embodiment;

FIG. 4 is a block configuration diagram schematically illustrating a cooling structure of a projector according to a first modification; and

FIG. 5 is a block configuration diagram schematically illustrating a configuration of the projector according to the first modification.

### DETAILED DESCRIPTION OF THE INVENTION

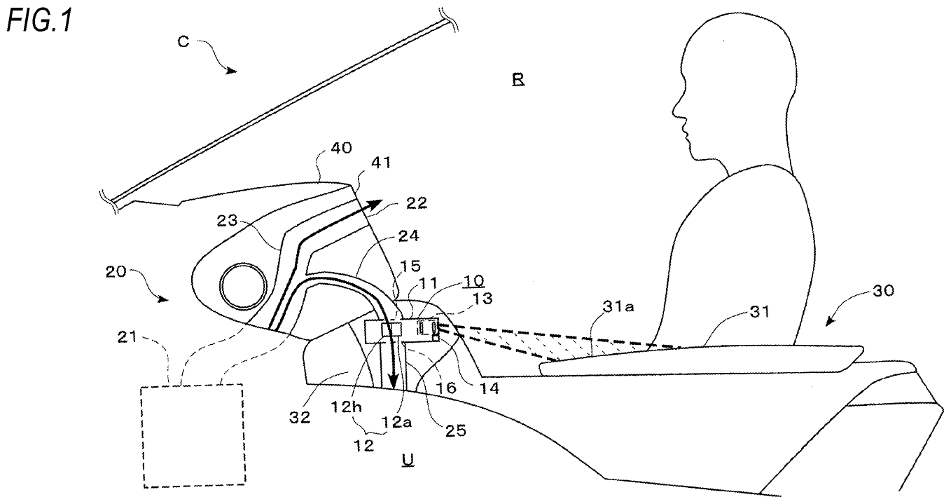

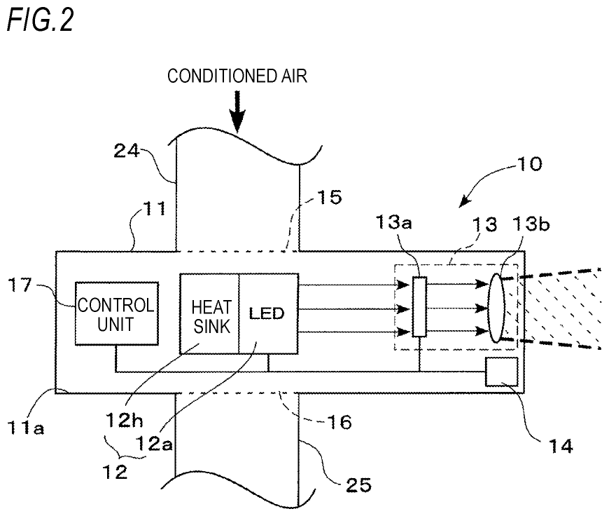

Hereinafter, the embodiments in which a cooling structure of an on-vehicle projector according to the invention is embodied will be described with reference to the drawings. First, a first embodiment is described with reference to FIGS. 1 and 2.

As illustrated in FIG. 1, an instrument panel 40 is attached to the vehicle front side in a vehicle cabin R of a vehicle C, and a center panel part 41 is formed almost in the center of the instrument panel 40 in a vehicle width direction. Almost in the center in the vehicle cabin R, a console 30 is arranged on the floor between a driver seat (not illustrated) and a passenger seat.

The console 30 is configured such that an armrest part 31 for an occupant to rest the elbow is formed on the vehicle rear-side portion, and an upper surface of a resin console body is covered with a skin material. In addition, the projector 10 is attached inside a front console part 32 positioned on the vehicle front side in the console 30.

The projector 10 is a device configured to project an image to the armrest part 31 of the console 30 and to enable a pointing operation to operate the image with a hand. Specifically, as illustrated in FIG. 2, the projector 10 includes a case 11, a light source 12, an image projection part 13, a detection part 14, and a control part 17.

The case 11 is a box-shaped case and accommodates components of the projector 10 in an internal space 11a. A first vent hole 15 and a second vent hole 16 which are arranged to face each other with the heat sink 12h of the light source 12 interposed therebetween are formed in the case 11. The first vent hole 15 is closed on the upper side of the case 11, and the second vent hole 16 is closed on the lower side.

The light source 12 is a device capable of emitting light and includes a light emitting diode (LED) 12a and a heat sink 12h provided integrally with the light emitting diode (LED) 12a. A heat radiation fin (not illustrated) is provided in the heat sink 12h.

The image projection part 13 includes a liquid crystal panel 13a as an optical modulation part and a projection lens 13b as a projection optical system. The light emitted from the light source 12 is modulated by penetrating the liquid crystal panel 13a, and the image light corresponding to the image data is formed for each color light. The formed image light of each color is combined to be enlarged and projected on a projection surface 31a of the armrest part 31 as a screen by the projection lens 13b.

The detection part 14 is a device which detects a position of an object on the projection surface 31a which is projected by the image projection part 13 and is configured by a camera, for example. For example, when the occupant performs a gesture on the projection surface 31a with a hand, the detection part 14 detects the gesture. According to the gesture, various operations can be performed in the projector 10.

The control part 17 is a control device which is electrically connected to the light source 12, the image projection part 13, and the detection part 14 to control those parts, and includes a CPU, a ROM, a RAM, and the like.

Next, an air conditioner 20 is described with reference to FIG. 1. The air conditioner 20 for controlling the temperature in the vehicle cabin R is mounted in the vehicle C. For example, the air conditioner 20 includes a blower unit 21 having a blower motor, a register 22 as an outlet for blowing a conditioned air into the vehicle cabin R, and a main duct 23 as a cylindrical body for connecting the blower unit 21 and the register 22. In the embodiment, a branch duct 24 which is branched from the main duct 23 to be connected to the first vent hole 15 of the projector 10 and an exhaust duct 25 in which one end thereof is connected to the second vent hole 16 of the projector 10, and the other end thereof is closed toward an underfloor U are provided.

A blower unit 21 is fixed to the instrument panel 40 in the state of being accommodated in the space on the inner surface side of the instrument panel 40. The register 22 is a central register which is provided in the center panel part 41 almost in the center of the instrument panel 40 in the vehicle width direction. The inner temperature in the vehicle cabin R is adjusted by the conditioned air blown out from the register 22 and another air outlet (not illustrated) (for example, a side register (not illustrated) provided near the end part, or an air outlet toward the feet of the occupant).

The main duct 23 is a hollow cylindrical member. One end part thereof is connected to the blower unit 21, and the other end part thereof is connected to the register 22. In addition, the main duct 23 is branched to the branch duct 24 in the middle of being guided to the register 22. The branch duct 24 extends downward at the center panel part 41 and is connected to the first vent hole 15 of the projector 10.

Next, the action of each part in the cooling structure of the on-vehicle projector of the embodiment is described. When the operation of the projector 10 starts to supply power to an LED 12a of the light source 12, the heat is generated while the light is emitted, and the heat is conducted to the heat sink 12h.

On the other hand, when the blower unit 21 of the air conditioner 20 is operated according to the start of the operation of the vehicle C, the conditioned air is sent through the main duct 23, and most of the conditioned air is blown from the register 22 into the vehicle cabin R. In addition, the conditioned air is also sent into the branch duct 24 branched from the main duct 23 to be sent from the first vent hole 15 of the projector 10 into the internal space 11a of the case 11, thereby cooling the light source 12 formed by integrating the LED 12a and the heat sink 12h. The conditioned air after cooling the light source 12 is discharged from the second vent hole 16 to the outside of the internal space 11a of the case 11, and is further discharged to the space of the underfloor U through the exhaust duct 25.

As apparent from the above description, the cooling structure of the on-vehicle projector of this embodiment is a cooling structure for cooling the projector 10 mounted in the vehicle C. The cooling structure includes the light source 12, the image projection part 13 which projects an image based on the light emitted from the light source 12 and an image signal, the projector 10 which includes the internal space 11a in which the light source 12 is arranged and the first and second vent holes 15 and 16 for ventilation with the outside, and the branch duct 24 as an air introduction part for introducing the conditioned air sent from the air conditioner 20 mounted in the vehicle C to the internal space 11a through the first vent hole 15.

With this configuration, the conditioned air sent from the air conditioner 20 mounted in the vehicle C is introduced from the branch duct 24 to the internal space 11a through the first vent hole 15. Therefore, the heating light source 12 can be cooled effectively and the conditioned air can be exhausted from the second vent hole 16. Thus, the effect of eliminating the thermal effect such as the decrease of life is obtained while the luminance of the light source in the on-vehicle projector is secured.

In the embodiment, the branch duct 24 is used which is branched from the main duct 23 for connecting the blower unit 21 of the air conditioner 20 and the register 22 which is an air outlet to the vehicle cabin R. Thus, the air introduction part of the invention can be realized with a minimum change to the configuration of an existing air conditioner.

In the embodiment, the heat sink 12h for heat radiation is provided integrally in the light source 12, and the first and second vent holes 15 and 16 are arranged to face each other with the heat sink 12h interposed therebetween. Thus, the cooling can be performed more effectively by directly discharging the conditioned air to the heat sink 12h which is a heat radiation part of the light source 12.

In the embodiment, the exhaust duct 25 is provided as an air lead-out part which is provided to communicate with the second vent hole 16 and leads out the air discharged from the second vent hole 16 to the underfloor U of the vehicle cabin R.

With the configuration, the conditioned air of which the temperature is increased while cooling the light source 12 is prevented from being exhausted into the vehicle cabin R, thereby avoiding an adverse effect on the temperature control of the vehicle cabin R. Further, the conditioned air can be secondarily used to cool high temperature equipment, such as an HV or EV battery, which is provided on the underfloor U side.

In the embodiment, the projector 10 projects an image to the armrest part 31 forming the upper surface of the console 30 which is provided between the driver seat and the passenger seat in the vehicle cabin R by the image projection part 13. In the console 30, the projector 10 is attached to the front console part 32 adjacent to the vehicle rear side of the instrument panel 40 provided on the vehicle front side in the vehicle cabin R.

With the configuration, by arranging the projector 10 in the front console part 32, the image can be reliably projected to the armrest part 31 without any obstacle and the light source 12 can be cooled effectively by introducing the conditioned air from the adjacent instrument panel 40 side.

In the embodiment, the projector 10 includes the detection part 14 which detects the position of the object on the projection surface 31a projected by the image projection part 13. Thus, in the projector which is configured to detect the gesture on the projection surface 31a, the heating light source 12 can be cooled effectively.

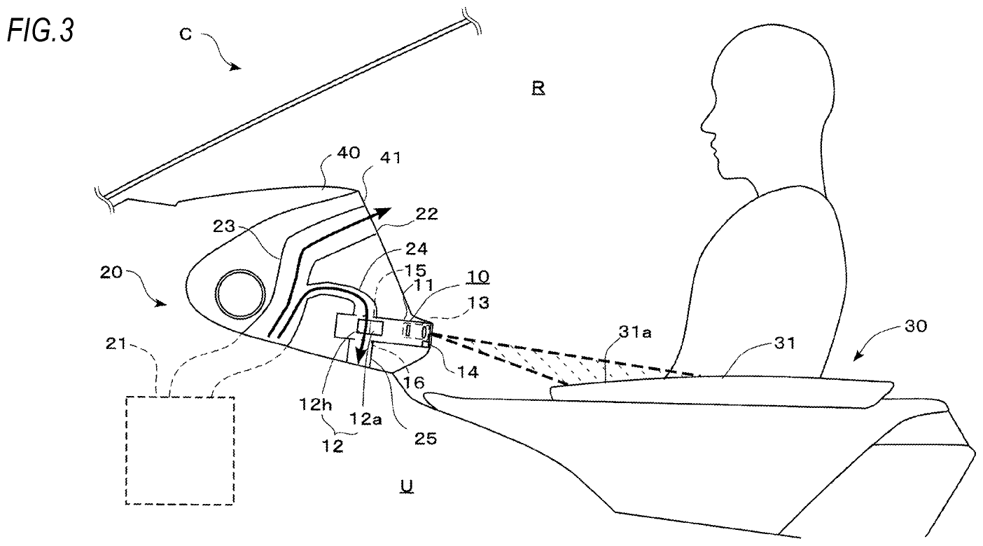

Next, a second embodiment of the invention will be described with reference to FIG. 3. The same components as those of the first embodiment are denoted by the same reference numerals, and the detailed descriptions thereof are omitted. In the above-described first embodiment, the projector 10 is attached to the front console part 32 adjacent to the vehicle rear side of the instrument panel 40. However, in this embodiment, the projector 10 is attached to the instrument panel 40.

With the configuration, by arranging the projector 10 in the instrument panel 40, the image can be reliably projected to the armrest part 31 without any obstacle and the conditioned air which is sent from the blower unit 21 of the air conditioner 20 is introduced from the main duct 23 in the instrument panel 40 to the projector 10 through the branch duct 24, so that the light source 12 can be cooled effectively.

The invention is not limited to the above-described embodiments, and various modifications can be made without departing the spirit and the scope of the invention.

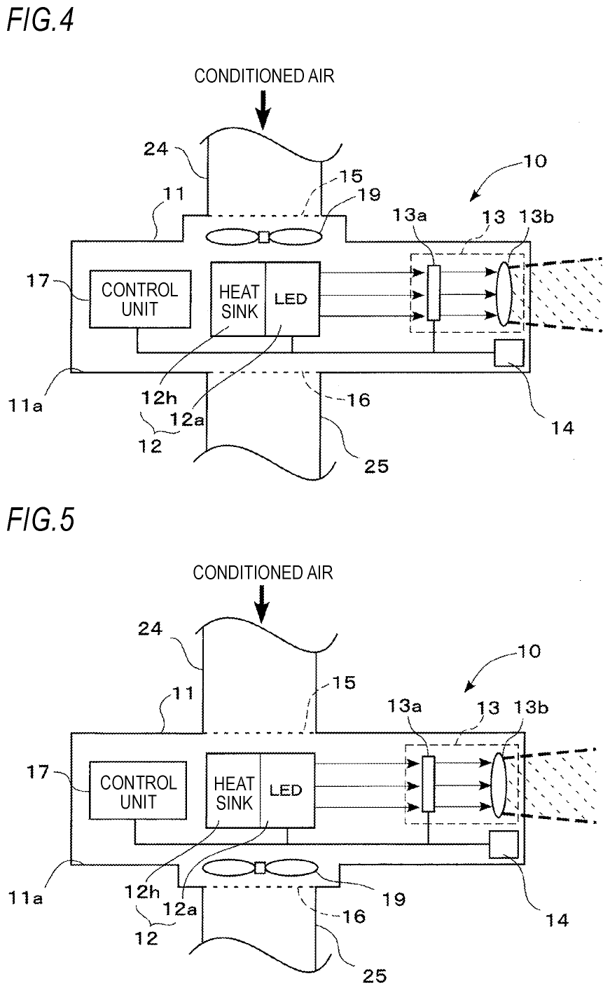

For example, as in a first modification illustrated in FIG. 4, in the projector 10, an air blowing fan 19 as an air flow generation part which forcibly generates air flow in a direction from the first vent hole 15 toward the second vent hole 16 may be provided near the first vent hole 15. With the configuration, the conditioned air introduced from the branch duct 24 is forcibly sent from the first vent hole 15 into the internal space 11a by the air blowing fan 19, and thus the light source 12 can be cooled more effectively.

Otherwise, as in a second modification illustrated in FIG. 5, in the projector 10, the air blowing fan 19 as the air flow generation part which forcibly generates the air flow in a direction from the first vent hole 15 toward the second vent hole 16 may be provided near the second vent hole 16. With the configuration, exhaust air is forcibly sucked from the second vent hole 16 by the air blowing fan 19, so that the light source 12 can be cooled more effectively.

In each embodiment described above, the arrangement of the projector 10, the branch duct 24, and the exhaust duct 25 is merely one example. The invention is not limited to the above-described arrangement. For example, if the arrangement can be made such that air is exhausted from the second vent hole 16 to the underfloor U, the exhaust duct 25 can be omitted.

In the embodiments, the invention is exemplarily applied to the projector 10 including the detection part 14 which detects the position of the object on the projection surface 31a projected by the image projection part 13. However, the invention may be also applied to a projector having no detection part.

What is claimed is:

1. A cooling structure of an on-vehicle projector, comprising:
a projector including: a light source; an image projection part configured to project an image based on the light emitted from the light source and an image signal; and first and second vent holes configured to ventilate the internal space, in which the light source is arranged, with the outside; and
an air introduction part configured to introduce conditioned air, sent from an air conditioner mounted in a vehicle, to the internal space through the first vent hole.

2. The cooling structure according to claim 1, wherein
the air introduction part is a branch duct which is branched from a main duct connecting a blower unit of the air conditioner and an air outlet to a vehicle cabin.

3. The cooling structure according to claim 1, wherein
a heat sink for heat radiation is provided integrally in the light source, and
the first and second vent holes are arranged to face each other with the heat sink interposed therebetween.

4. The cooling structure according to claim 1, further comprising:
an air flow generation part which is provided in at least one of the first and second vent holes and forcibly generates air flow in a direction from the first vent hole toward the second vent hole.

5. The cooling structure according to claim 1, further comprising:
an air lead-out part which is provided to communicate with the second vent hole and leads out air discharged from the second vent hole to an underfloor of the vehicle cabin.

6. The cooling structure according to claim 1, wherein
the projector projects an image to an armrest part forming an upper surface of a console which is provided between a driver seat and a passenger seat in the vehicle cabin by the image projection part.

7. The cooling structure according to claim 6, wherein
the projector is attached to an instrument panel provided on a vehicle front side in the vehicle cabin.

8. The cooling structure according to claim 6, wherein
in the console, the projector is attached to a front console part adjacent to a vehicle rear side of an instrument panel provided on a vehicle front side in the vehicle cabin.

9. The cooling structure according to claim 1, wherein
the projector includes a detection part configured to detect the position of an object on a projection surface projected by the image projection part.
